(19) United States
(12) Patent Application Publication
(10) Pub. No.: US 2025/0357396 A1
(43) Pub. Date: Nov. 20, 2025

(54) SEMICONDUCTOR DEVICES HAVING NON-UNIFORM PATTERN DENSITY FOR HYBRID BONDING

(71) Applicant: GlobalFoundries Singapore Pte. Ltd., Singapore (SG)

(72) Inventors: XIAODONG LI, Singapore (SG); WANBING YI, Singapore (SG); WEICHU QIU, Singapore (SG); CHUNG-SHOU CHEN, Singapore (SG); KELVIN PHOK YONG CHONG, Singapore (SG); GERARDO GERRY SARCILLA DIZON, Singapore (SG)

(21) Appl. No.: 18/666,789

(22) Filed: May 16, 2024

(51) Int. Cl. H01L 23/00; H01L 25/065

(52) U.S. Cl. CPC H01L 24/06; H01L 24/08; H01L 24/32; H01L 25/0657; H01L 2224/06132; H01L 2224/08145; H01L 2224/32145; H01L 2924/19011

(57) ABSTRACT

The embodiments herein relate to semiconductor devices having a non-uniform pattern density for hybrid bonding. A semiconductor structure is provided. The semiconductor structure may include a semiconductor device having a substrate, a device region over the substrate, a bonding region over the device region, and a plurality of bonding structures in the bonding region. The bonding region may include a first bonding area having a first pattern density, a second bonding area having a second pattern density adjacent to the first bonding area, and a third bonding area having a third pattern density adjacent to the second bonding area. The plurality of bonding structures in the bonding region may include a first bonding structure in the first bonding area, a second bonding structure in the second bonding area, and a third bonding structure in the third bonding area.

### TECHNICAL FIELD

The present disclosure relates generally to semiconductor devices, and more particularly to semiconductor devices having a non-uniform pattern density for hybrid bonding.

### BACKGROUND

A three-dimensional (3D) semiconductor structure can be formed by stacking and bonding semiconductor devices in the form of wafers and/or dies, and interconnecting them vertically using techniques such as through-substrate vias (TSVs) or copper-to-copper connections. This allows the resulting semiconductor structure to function as a single device, achieving better performance with reduced power consumption and a smaller footprint than conventional planar processes. One of the most promising techniques for bonding semiconductor devices is hybrid bonding. Hybrid bonding involves bonding two semiconductor devices through metal-to-metal bonding and dielectric-to-dielectric bonding.

To meet the growing needs of the semiconductor industry, improved structures of semiconductor devices for hybrid bonding are required.

### SUMMARY

To achieve the foregoing and other aspects of the present disclosure, semiconductor devices having a non-uniform pattern density for hybrid bonding are presented.

According to an aspect of the present disclosure, a semiconductor structure is provided. The semiconductor structure may include a semiconductor device having a substrate, a device region over the substrate, a bonding region over the device region, and a plurality of bonding structures in the bonding region. The bonding region may include a first bonding area having a first pattern density, a second bonding area having a second pattern density adjacent to the first bonding area, and a third bonding area having a third pattern density adjacent to the second bonding area. The plurality of bonding structures in the bonding region may include a first bonding structure in the first bonding area, a second bonding structure in the second bonding area, and a third bonding structure in the third bonding area.

### BRIEF DESCRIPTION OF THE DRAWINGS

The embodiments of the present disclosure will be better understood from a reading of the following detailed description, taken in conjunction with the accompanying drawings:

FIG. 1 is a cross-sectional view of a bonded semiconductor structure, according to an embodiment of the disclosure.

FIG. 2 is a top view of a bonding layer of a semiconductor device, according to an embodiment of the disclosure.

FIGS. 3-6 are top views of a bonding layer of various semiconductor devices, according to embodiments of the disclosure.

For simplicity and clarity of illustration, the drawings illustrate the general manner of construction, and certain descriptions and details of well-known features and techniques may be omitted to avoid unnecessarily obscuring the discussion of the described embodiments of the disclosure.

Additionally, features in the drawings are not necessarily drawn to scale. For example, the dimensions of some of the features in the drawings may be exaggerated relative to other features to help improve the understanding of the embodiments of the device. The same reference numerals in different drawings denote the same features, while similar reference numerals may, but do not necessarily, denote similar features.

### DETAILED DESCRIPTION

The present disclosure relates to semiconductor devices having a non-uniform pattern density for hybrid bonding. The semiconductor devices may be stacked and bonded using a bonding technique, such as hybrid bonding, to form bonded semiconductor structures. As used herein, the term “bonded semiconductor structures” refers to semiconductor devices that are stacked on each other and bonded together by wafer-to-wafer bonding, die-to-wafer bonding, or die-to-die bonding.

The semiconductor devices described herein may be manufactured in any number of ways using any number of different tools, and are formed with dimensions per their intended design. Generally, methodologies and tools employed to manufacture semiconductor devices have been adopted from known semiconductor technologies. For example, semiconductor devices are manufactured by building electronic components, such as transistors, capacitors, and interconnection structures, on bulk or composite semiconductor substrates.

Various embodiments of the present disclosure are now described in detail with accompanying drawings. It is noted that like and corresponding features are referred to by the use of the same reference numerals. The embodiments disclosed herein are exemplary, and not intended to be exhaustive or limiting to the disclosure.

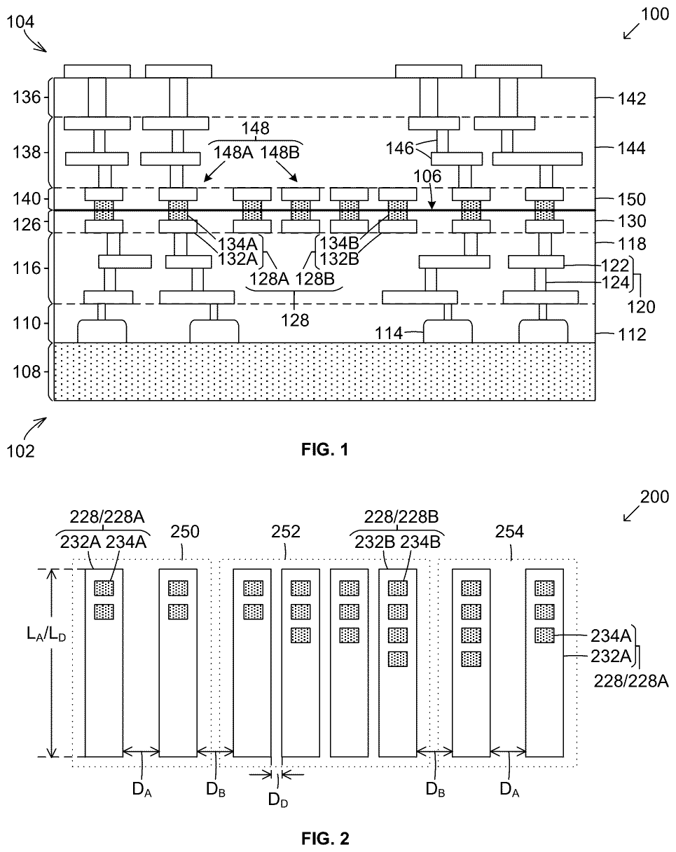

FIG. 1 is a cross-sectional view of a semiconductor structure 100, according to an embodiment of the disclosure. The semiconductor structure 100 may be non-monolithic. As used herein, the term “non-monolithic” refers to structures that include components that can be formed separately and then bonded together to form a bonded structure, such as the semiconductor structure 100. For example, the semiconductor structure 100 may include at least two components, such as a first semiconductor device 102 and a second semiconductor device 104.

The first semiconductor device 102 and the second semiconductor device 104 may be in wafer and/or die form that are formed monolithically. The first semiconductor device 102 and the second semiconductor device 104 may be stacked at a bonding interface 106 in a face-to-face orientation and bonded using a hybrid bonding technique. The term “hybrid bonding” refers to a direct permanent bonding technique between wafers and/or dies achieved through dielectric-to-dielectric bonding and metal-to-metal bonding, without the use of intermediate layers, such as solder or adhesives. The semiconductor structure 100 may include any suitable semiconductor devices, such as logic devices, power devices, or memory devices.

The first semiconductor device 102 may include a substrate 108. For purposes of description, the substrate 108 is illustrated and described as a bulk substrate. Alternatively, the substrate 108 may be a composite semiconductor substrate, such as a semiconductor-on-insulator (SOI) substrate. The substrate 108 may include a semiconductor material, such as silicon, silicon germanium, silicon carbide, or other II-VI or III-V semiconductor compounds.

The first semiconductor device 102 may further include a first device region 110 on the substrate 108. The first device region 110 may include an interlayer dielectric 112 formed from any number of dielectric layers (not shown) and one or more active electronic components 114 within the interlayer dielectric 112. The active electronic components 114 may have the ability to control the electrical current and may include transistors, triode vacuum tubes (valves), or tunnel diodes. The first device region 110 may, additionally or optionally, include passive electronic components (not shown). The passive electronic components may be incapable of controlling electrical current by means of another electrical signal and may include resistors, capacitors, or inductors. The interlayer dielectric 112 may include a dielectric material, such as silicon dioxide, silicon oxynitride, borophosphosilicate glass (BPSG), or undoped silicate glass (USG).

The first semiconductor device 102 may yet further include a first metallization region 116 over the first device region 110. The first metallization region 116 may include an interlayer dielectric 118 formed from any number of dielectric layers (not shown) and a plurality of first interconnects 120 within the interlayer dielectric 118. The first interconnects 120 may include horizontal conductive lines 122 and vertical conductive vias 124. The first interconnects 120 may be electrically connected to at least one of the active electronic components 114 in the first device region 110. The first interconnects 120 may include an electrically conductive material, such as tungsten, copper, cobalt, aluminum, or combinations thereof.

Additionally, the first semiconductor device 102 may include a first bonding region 126 over the first metallization region 116. The first bonding region 126 may be the region where the first semiconductor device 102 contacts and bonds to the second semiconductor device 104. The first bonding region 126 may include a plurality of bonding structures 128 electrically isolated from each other in a dielectric 130 formed from any number of dielectric layers (not shown). The dielectric 130 may include an electrically insulative material, for example, silicon dioxide, silicon oxynitride, borophosphosilicate glass (BPSG), or undoped silicate glass (USG). The bonding structures 128 may include a metallic material, such as tungsten, copper, cobalt, aluminum, or combinations thereof, and may preferably be the same metallic material as the first interconnects 120.

The bonding structures 128 may or may not have electrical functions. For example, the bonding structures 128 may include active bonding structures 128A and inactive bonding structures 128B. As used herein, the term “active” refers to components that have electrical functions and the term “inactive” refers to components that do not have electrical functions. Inactive components may be electrically floating and may be referred to as “dummy components”. The active bonding structures 128A may be electrically connected to at least one of the first interconnects 120 in the first metallization region 116, and may also be part of an electrical connection between the first semiconductor device 102 and the second semiconductor device 104. In contrast, the inactive bonding structures 128B may not be part of any electrical connection within the first semiconductor device 102 or between the first semiconductor device 102 and the second semiconductor device 104. Instead, the inactive bonding structures 128B may be used to increase the density of the bonding structures 128 for increased bonding yield and strength of the bonded semiconductor structure 100.

Each bonding structure 128 may include a horizontal line structure and a vertical via structure. For example, the active bonding structure 128A may include a horizontal active line 132A and at least one vertical active via 134A over and electrically connected to the active line 132A, and the inactive bonding structure 128B may include a horizontal inactive line 132B and at least one vertical inactive via 134B electrically connected to the inactive line 132B. In an embodiment of the disclosure, the active bonding structure 128A and the inactive bonding structure 128B may be identical in size and shape. In another embodiment of the disclosure, the active bonding structure 128A and the inactive bonding structure 128B may be different in size and/or shape.

Similar to the first semiconductor device 102, the second semiconductor device 104 may also include a second device region 136, a second metallization region 138, and a second bonding region 140. The second bonding region 140 may be in contact and adjoin with the first bonding region 126 of the first semiconductor device 102 at the bonding interface 106. The second semiconductor device 104 may, additionally or optionally, include a substrate (not shown) in contact with the second device region 136.

The second device region 136 may include an interlayer dielectric 142 formed from any number of dielectric layers (not shown), in which at least one active electronic component (not shown) and/or at least one passive electronic component (not shown) may be arranged in the interlayer dielectric 142. The second metallization region 138 may include an interlayer dielectric 144 formed from any number of dielectric layers (not shown) and a plurality of second interconnects 146 within the interlayer dielectric 144. The second interconnects 146 may be electrically connected to the electronic components in the second device region 136.

The second bonding region 140 may include a plurality of bonding structures 148 electrically isolated from each other in a dielectric 150 formed from any number of dielectric layers (not shown). The bonding structures 148 and the dielectric 150 may enable the second semiconductor device 104 to be respectively bonded to the first semiconductor device 102 at the bonding interface 106 through metal-to-metal bonding and dielectric-to-dielectric bonding. The bonding structures 148 may be similar to the bonding structures 128 in the first semiconductor device 102. For example, the bonding structures 148 may include active bonding structures 148A and inactive bonding structures 148B, and each bonding structure 148 may include a horizontal line structure and at least one vertical via structure over and electrically connected to the line structure. The active bonding structures 148A have electrical functions and may be part of an electrical connection between the second semiconductor device 104 and the first semiconductor device 102, while the inactive bonding structures 148B do not have electrical functions and may be electrically floating. The inactive bonding structures 148B may be used to increase the density of the bonding structures 148 for increased bonding yield and strength of the bonded semiconductor structure 100.

Additionally, the bonding structures 148 are designed to be aligned with and bonded to the bonding structures 128 in the first bonding region 126 with a one-to-one correspondence to bond the second semiconductor device 104 to the first semiconductor device 102 at the bonding interface 106. For example, the active bonding structure 148A is bonded to the active bonding structure 128A through metallic bonding, and the inactive bonding structure 148B is bonded to the inactive bonding structure 128B through metallic bonding. The dielectric 130 and the dielectric 150 are bonded together through molecular bonding. Even though FIG. 1 illustrates eight (8) bonding structures 128, 148, in the corresponding first bonding region 126 and the second bonding region 140, it may be noted that the number of bonding structures 128, 148 in the bonding regions 126, 140 may vary according to the design requirements of the bonded semiconductor structure 100.

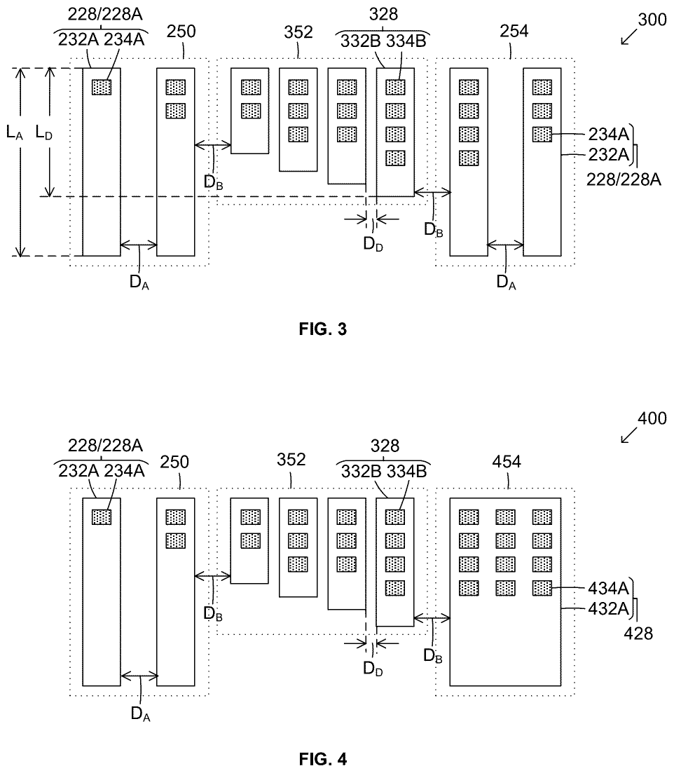

FIG. 2 is a top view of a plurality of bonding structures 228 in a bonding region 200 of a semiconductor device, according to an embodiment of the disclosure. The semiconductor device may be used to bond with another semiconductor device using a hybrid bonding technique to form a bonded semiconductor structure, similar to the bonded semiconductor structure 100 in FIG. 1. The bonding region 200 may be synonymous with the first bonding region 126 of the first semiconductor device 102 in FIG. 1. The bonding region 200 may include a bonding area 250, a bonding area 252 immediately adjacent to the bonding area 250, and a bonding area 254 immediately adjacent to the bonding area 252. Each bonding area 250, 252, 254 is diagrammatically shown by a dotted line for purposes of illustration.

The bonding structures 228 may be arranged in a dielectric layer and the dielectric layer is not shown for clarity purposes. The bonding structures 228 may include active bonding structures 228A and inactive bonding structures 228B. Whether a bonding structure 228 is used as an active bonding structure or an inactive bonding structure is determined by the electrical connection of the bonding structure, such as whether the bonding structure is connected to an active electronic component of the semiconductor device or external circuitry. For example, a bonding structure is an active bonding structure when the bonding structure has electrical functions, similar to the active bonding structures 128A of the first semiconductor device 102 in FIG. 1. In another example, a bonding structure is an inactive bonding structure when the bonding structure does not have electrical functions and may be electrically floating, similar to the inactive bonding structure 128B of the first semiconductor device 102 in FIG. 1.

The bonding structures 228 may be arranged in the bonding areas 250, 252, 254 of the bonding region 200 according to the electrical functionality of the bonding structures 228. For example, the active bonding structures 228A may be arranged in the bonding areas 250, 254, while the inactive bonding structures 228B may be arranged in the bonding area 252. The bonding areas 250, 254 may each include any number of active bonding structures 228A and may be referred to as active bonding areas 250, 254. Each active bonding structure 228A may include a horizontal active line 232A and at least one vertical active via 234A over and electrically connected to the active line 232A. The bonding area 252 may include any number of inactive bonding structures 228B and may be referred to as an inactive bonding area 252. Each inactive bonding structure 228B may include a horizontal inactive line 232B and at least one vertical inactive via 234B over and electrically connected to the inactive line 232B.

The configuration of each bonding area 250, 252, 254 may vary according to the design requirements of the semiconductor device. For example, each active bonding area 250, 254 may include any number of active lines 232A and active vias 234A connected to each active line 232A. A pattern density gradient may result between the two active bonding areas 250, 254, which may be undesirable for the semiconductor device. For example, pattern inhomogeneity may cause patterning errors during the fabrication of the semiconductor device, or may result in mechanical and electrical implications during the bonding of the semiconductor device to form a bonded semiconductor structure. The pattern density gradient between the two active bonding areas 250, 254 may be lowered by forming the inactive bonding area 252 between the active bonding areas 250, 254. The inactive bonding area 252 may include any number of inactive lines 232B and inactive vias 234B connected to each inactive line 232B. The inactive bonding area 252 may serve to bridge the pattern density differences between the active bonding areas 250, 254, resulting in a gentler pattern density gradient between the active bonding areas 250, 254, which changes relatively gradually as compared to a more abrupt change without the inactive bonding area 252. The number of inactive bonding structures 228B may be determined according to the design requirement of the bonded semiconductor structure that will be ultimately formed using the semiconductor device, which the bonding region 200 is part of. A non-uniform pattern density of bonding structures 228 may extend across the bonding region 200.

The pattern density of the bonding areas 250, 252, 254 may also affect the antenna ratio of the bonding areas 250, 252, 254. As used herein, the term “antenna ratio” refers to a ratio between the surface area of a line, such as the active line 232A, and the total surface area of vias that are connected to the line, such as the active vias 234A. Since the pattern densities of the active bonding areas 250, 254 and the inactive bonding area 252 may vary, the corresponding antenna ratios may also be different and have unique values. The higher the antenna ratio of a bonding area, the higher the probability of weakened bonding strength of the ultimately formed bonded semiconductor structure. The bonding strength may be weakened due to the possibility of increased recess of the bonding structures, such as the active vias 234A and the inactive vias 234B. The weakened bonding strength may result in poor bonding to the other semiconductor device, such as the second semiconductor device 104 in FIG. 1, and impact the bonding yield of the bonded semiconductor structure. Accordingly, the design of the inactive bonding area 252 may consider antenna ratio when determining the number and configuration of inactive bonding structures 228B to be placed in the inactive bonding area 252. In an embodiment of the disclosure, the antenna ratio of the inactive bonding area 252 is between 50 to 100.

The active lines 232A in the active bonding areas 250, 254 and the inactive lines 232B in the inactive bonding area 252 may be substantially parallel. The inactive line 232B and the proximate active line 232A may be spaced apart by a distance D_{B}. In an embodiment of the disclosure, the distance D_{B} is at most two (2) micrometers. The inactive lines 232B may be spaced apart from each other by a distance D_{D} in the inactive bonding area 252. In an embodiment of the disclosure, the distance D_{D} is no wider than the distance D_{B}, for example, the distance D_{D} may be equal to or less than two (2) micrometers. The active lines 232A in each active bonding area 250, 254 may be spaced apart from each other by a distance D_{A}. In an embodiment of the disclosure, the distance D_{A} may be wider than the distance D_{D}. In another embodiment of the disclosure, the distance D_{A} may be substantially similar to the distance D_{B}.

The inactive lines 232B may have a length L_{D} at most as long as the length L_{A} of the active line 232A. As illustrated in FIG. 2, the length L_{D} of the inactive line 232B is substantially equal to the length L_{A} of the active line 232A. As used herein, the term “length” is the longest dimension of a feature. The inactive vias 234B may not be arranged throughout the inactive line 232B and may be arranged in proximity to the active vias 234A in the adjacent active bonding areas 250, 254.

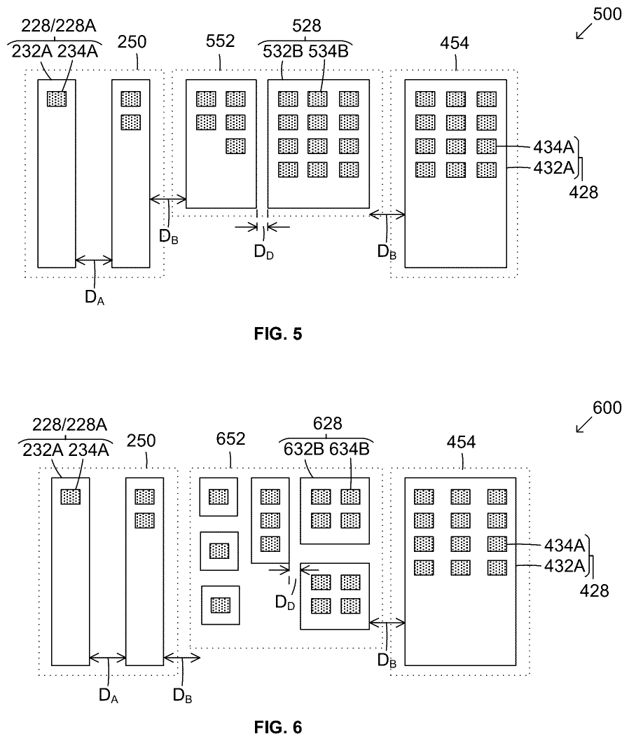

FIG. 3 is a top view of a plurality of bonding structures 228, 328 in a bonding region 300 of a semiconductor device, according to an embodiment of the disclosure. The semiconductor device may be used to bond with another semiconductor device using a hybrid bonding technique to form a bonded semiconductor structure, similar to the bonded semiconductor structure 100 in FIG. 1. The bonding region 300 may be similar to the bonding region 200 in FIG. 2. For example, the bonding region 300 may include active bonding areas 250, 254 and an inactive bonding area 352 between the active bonding areas 250, 254. The active bonding areas 250, 254 may each include at least one active bonding structure 228A including a horizontal active line 232A and a vertical active via 234A over and electrically connected to the active line 232A. The inactive bonding area 352 may include at least one inactive bonding structure 328 including a horizontal inactive line 332B and a vertical inactive via 334B over and electrically connected to the inactive line 332B.

Unlike the bonding region 200 in FIG. 2, the inactive lines 332B of the inactive bonding structures 328B may have a length L_{D} shorter than the length L_{A} of the active lines 232A of the active bonding structures 228A. The inactive vias 334B may not be arranged throughout the inactive line 332B and may be arranged in proximity to the active vias 234A in the adjacent active bonding areas 250, 254. The number of inactive vias 334B may vary according to the design requirements of the bonding region 300 and/or the ultimately formed bonded semiconductor structure. For example, the inactive bonding area 352 may reduce pattern density inhomogeneity between the active bonding areas 250, 254 by reducing the pattern density gradient between the active bonding areas 250, 254. The inactive bonding area 352 may include any number of inactive bonding structures 328 while keeping the antenna ratio of the inactive bonding area 352 between 50 to 100.

FIG. 4 is a top view of a plurality of bonding structures 228, 328, 428 in a bonding region 400 of a semiconductor device, according to an embodiment of the disclosure. The semiconductor device may be used to bond with another semiconductor device using a hybrid bonding technique to form a bonded semiconductor structure, similar to the bonded semiconductor structure 100 in FIG. 1. The bonding region 400 may be similar to the bonding region 300 in FIG. 3. For example, the bonding region 400 may include active bonding areas 250, 454 and an inactive bonding area 352 between the active bonding areas 250, 454. However, unlike the active lines 232A in the bonding area 254 where the active vias 234A are arranged in a single row, the active vias 434A of the active bonding area 454 may be arranged in an array configuration of rows and columns.

FIG. 5 is a top view of a plurality of bonding structures 228, 428, 528 in a bonding region 500 of a semiconductor device, according to an embodiment of the disclosure. The semiconductor device may be used to bond with another semiconductor device using a hybrid bonding technique to form a bonded semiconductor structure, similar to the bonded semiconductor structure 100 in FIG. 1. The bonding region 500 may be similar to the bonding region 400 in FIG. 4. For example, the bonding region 500 may include active bonding areas 250, 454 and an inactive bonding area 552 between the active bonding areas 250, 454. However, unlike the bonding region 400 where the inactive vias 334B are arranged in a single row, the inactive bonding vias 532B of the inactive bonding area 552 may be arranged in an array configuration of rows and columns. The inactive line 532A may be spaced from a proximate active line 232A, 432A by the distance D_{B}, and the distance D_{B} may be at most two (2) micrometers. The antenna ratio of the inactive bonding area 552 may be between 50 to 100.

FIG. 6 is a top view of a plurality of bonding structures 228, 628, 454 in a bonding region 600 of a semiconductor device, according to an embodiment of the disclosure. The semiconductor device may be used to bond with another semiconductor device using a hybrid bonding technique to form a bonded semiconductor structure, similar to the bonded semiconductor structure 100 in FIG. 1. The bonding region 600 may be similar to the bonding region 500 in FIG. 5. For example, the bonding region 600 may include active bonding areas 250, 454 and an inactive bonding area 652 between the active bonding areas 250, 454.

Unlike the inactive bonding area 552 in the bonding region 500, the inactive bonding area 652 may include various configurations of the inactive bonding structures 628B, for example, an inactive line 632B having a single inactive via 634B, an inactive line 632B having inactive vias 634B in a row, and an inactive line 632B having inactive vias 634B in an array configuration of rows and columns. The inactive line 632B may be spaced from a proximate active line 232A, 432A by the distance D_{B}, and the distance D_{B} may be at most two (2) micrometers. The antenna ratio of the inactive bonding area 652 may be between 50 to 100. The inactive lines 632B may be spaced apart from each other by a minimum distance D_{D}. The antenna ratio of the inactive bonding area 652 may be between 50 to 100. In an embodiment of the disclosure, the distance D_{D} may be no wider than the distance D_{B}, for example, the distance D_{D} may be equal to or less than two (2) micrometers.

As presented above, semiconductor devices having a non-uniform pattern density for hybrid bonding are disclosed. Each semiconductor device may be part of a semiconductor structure formed from a bonding technique, such as a hybrid bonding technique. The hybrid bonding technique may include a combination of molecular bonding between dielectric layers and metallic bonding between bonding structures to achieve permanent bonding.

The semiconductor structure may include a semiconductor device as disclosed, and the semiconductor device may include a substrate, a device region over the substrate, a bonding region over the device region, and a plurality of bonding structures in the bonding region. The bonding region may include a first bonding area having a first antenna ratio, a second bonding area having a second antenna ratio adjacent to the first bonding area, and a third bonding area having a third antenna ratio adjacent to the second bonding area. The plurality of bonding structures in the bonding region may include a first bonding structure in the first bonding area, a second bonding structure in the second bonding area, and a third bonding structure in the third bonding area.

The terms “top”, “bottom”, “over”, “under”, and the like in the description and the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact, and may also include embodiments in which additional features may be formed by interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of features is not necessarily limited to those features but may include other features not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

Furthermore, approximating language, as used herein throughout the specification and claims, may be applied to modify any quantitative representation that could permissibly vary without resulting in a change in the basic function to which it is related. Accordingly, a value modified by a term or terms, such as “approximately”, “about,” or “substantially” is not limited to the precise value specified. In some instances, the approximating language may correspond to the precision of an instrument for measuring the value. In other instances, the approximating language may correspond to within normal tolerances of the semiconductor industry. For example, “substantially coplanar” means substantially in a same plane within normal tolerances of the semiconductor industry, and “substantially perpendicular” means at an angle of 90 degrees plus or minus a normal tolerance of the semiconductor industry.

While several exemplary embodiments have been presented in the above-detailed description of the device, it should be appreciated that a number of variations exist. It should further be appreciated that the embodiments are only examples, and are not intended to limit the scope, applicability, dimensions, or configuration of the device in any way. Rather, the above-detailed description will provide those skilled in the art with a convenient road map for implementing an exemplary embodiment of the device, it is understood that various changes may be made in the function and arrangement of features and methods of fabrication described in an exemplary embodiment without departing from the scope of this disclosure as set forth in the appended claims.

What is claimed is:

1. A semiconductor structure, comprising:
a semiconductor device including:
a substrate;
a device region over the substrate;
a bonding region over the device region, wherein the bonding region includes a first bonding area having a first pattern density, a second bonding area having a second pattern density adjacent to the first bonding area, and a third bonding area having a third pattern density adjacent to the second bonding area; and
a plurality of bonding structures in the bonding region including a first bonding structure in the first bonding area, a second bonding structure in the second bonding area, and a third bonding structure in the third bonding area.

2. The semiconductor structure of claim 1, wherein the first pattern density is higher than the second pattern density.

3. The semiconductor structure of claim 2, wherein the second pattern density is higher than the third pattern density.

4. The semiconductor structure of claim 3, wherein the second bonding structure is electrically floating and does not have electrical functions.

5. The semiconductor structure of claim 4, wherein the first and third bonding structures are active bonding structures having electrical functions.

6. The semiconductor structure of claim 1, wherein the first, second, and third bonding structures each comprises:
a horizontal line structure; and
at least one vertical via structure electrically connected to the line structure.

7. The semiconductor structure of claim 6, wherein the line structure of the first, second, and third bonding structures are substantially parallel.

8. The semiconductor structure of claim 6, wherein the second bonding area further comprises a fourth bonding structure immediately between the first and second bonding structures, wherein the fourth bonding structure is spaced apart from the first bonding structure by a first distance and from the second bonding structure by a second distance different from the first distance.

9. The semiconductor structure of claim 8, wherein the first distance is wider than the second distance.

10. The semiconductor structure of claim 9, wherein the first distance is at most two micrometers.

11. The semiconductor structure of claim 6, wherein the line structure of the second bonding structure has a length substantially equal to the line structure of the first bonding structure.

12. The semiconductor structure of claim 6, wherein the line structure of the second bonding structure has a shorter length than the line structure of the first bonding structure.

13. The semiconductor structure of claim 12, wherein the second bonding area further comprises a fourth bonding structure between the first and second bonding structures, wherein the fourth bonding structure has a shorter length than the line structure of the first bonding structure and a longer length than the line structure of the second bonding structure.

14. The semiconductor structure of claim 6, wherein the at least one via structure is part of a plurality of via structures, and the plurality of via structures is arranged in an array configuration of rows and columns.

15. The semiconductor structure of claim 1, wherein the first bonding area has a first antenna ratio, the second bonding area has a second antenna ratio lower than the first antenna ratio, and the third bonding area has a third antenna ratio lower than the second pattern density.

16. The semiconductor structure of claim 1, wherein the semiconductor device is a first semiconductor device, further comprising a second semiconductor device including a fourth bonding structure, a fifth bonding structure, and a sixth bonding structure bonded to the first, second, and third bonding structures, respectively, at a bonding interface.

17. The semiconductor structure of claim 16, wherein the second bonding structure is electrically isolated from the first and third bonding structures by a first dielectric layer, and the fifth bonding structure is electrically isolated from the fourth and sixth bonding structures by a second dielectric layer, wherein the first dielectric layer and the second dielectric layer are bonded at the bonding interface.

18. The semiconductor structure of claim 17, wherein the bonding interface extends across the semiconductor structure.

19. The semiconductor structure of claim 16, wherein the fourth and sixth bonding structures are active bonding structures having electrical functions.

20. The semiconductor structure of claim 19, wherein the fifth bonding structure is electrically floating and does not have electrical functions.
